(19) United States
(12) Patent Application Publication
(10) Pub. No.: US 2025/0273478 A1
(43) Pub. Date: Aug. 28, 2025

(54) INFRARED LASER DEBOND PROCESS FOR FUSION-BONDED OR HYBRID-BONDED DIE COMPLEXES ON REUSABLE CARRIER WAFERS

(71) Applicant: Intel Corporation, Santa Clara, CA (US)

(72) Inventors: Thomas L. SOUNART, Chandler, AZ (US); Adel A. ELSHERBINI, Chandler, AZ (US); Johanna M. SWAN, Scottsdale, AZ (US); Shawna M. LIFF, Scottsdale, AZ (US); Tushar TALUKDAR, Wilsonville, OR (US); Kimin JUN, Portland, OR (US); Henning BRAUNISCH, Phoenix, AZ (US); Paul NORDEEN, Portland, OR (US)

(21) Appl. No.: 18/584,921

(22) Filed: Feb. 22, 2024

(51) Int. Cl. H01L 21/48; H01L 23/498

(52) U.S. Cl. CPC H01L 21/4842; H01L 21/4825; H01L 21/486; H01L 23/49822; H01L 23/49827

(57) ABSTRACT

Embodiments disclosed herein comprise a method of forming an electronic device. In an embodiment, the method comprises positioning a first structure over a second structure, where the first structure comprises a first electrical pad over a carrier substrate. In an embodiment, the first structure is mechanically coupled to the carrier substrate by a debond film, and the second structure comprises a second electrical pad. The method may further comprise bonding the first electrical pad to the second electrical pad with a hybrid bonding process. The method may further comprise ablating at least a portion of the debond film with a laser with a wavelength in an infrared range. In an embodiment, the method further comprises removing the carrier substrate.

### BACKGROUND

Advanced packaging process flows often employ temporary carriers for assembly processes. These carriers are typically glass wafers with an organic adhesive and release layer that is decomposed thermally or by UV laser absorption when the overlying substrate needs to be released from the carrier. However, such solutions have a high total thickness variation (TTV) (e.g., up to approximately 5 μm or larger). The glass wafers are also not compatible with many silicon wafer handling tools present within a fabrication facility.

Another approach for carrier solutions is to use a silicon carrier wafer. In such an embodiment, the bond between the wafer and the overlying interposer (or other structure) is not deactivated. Instead, the silicon wafer is thinned with a grinding process that can ultimately remove the entire silicon carrier wafer. This is an expensive process because carriers cannot be reused. Additionally, there is a risk of damage or degradation to the overlying structure during the recessing process. Another solution may include the use of a thermal release bonding film. However, the temperature limit for many interposer solutions is less than approximately 200° C. Thermal bond layers also have a high thickness without a high degree of uniformity (i.e., they may have a high TTV).

### BRIEF DESCRIPTION OF THE DRAWINGS

FIG. 1A is a cross-sectional illustration of a carrier with a debond film over the carrier, in accordance with an embodiment.

FIG. 1B is a cross-sectional illustration of a carrier with a multi-layer debond film, in accordance with an embodiment.

FIG. 1C is a cross-sectional illustration of a carrier with a multi-layer debond film, in accordance with an embodiment.

FIGS. 2A-2H are cross-sectional illustrations depicting a process for hybrid bonding pads together using a carrier with a debond film that is released with an infrared (IR) laser, in accordance with an embodiment.

FIG. 3 is a process flow diagram of a process for making hybrid bonding connections between pads through the use of a debond film that is released with an IR laser, in accordance with an embodiment.

FIGS. 4A-4F are cross-sectional illustrations depicting a process for wafer-level hybrid bonding through the use of a carrier with a debond film that is released with an IR laser, in accordance with an embodiment.

FIGS. 5A-5G are cross-sectional illustrations depicting a process for a wafer-level hybrid bonding of an array of dies coupled to a receiving substrate through the use of a carrier with a debond film that is released with an IR laser, in accordance with an embodiment.

FIGS. 6A-6G are cross-sectional illustrations depicting a process for assembling a multi-die system with hybrid bonding between dies using a carrier with a debond film that is released with an IR laser, in accordance with an embodiment.

FIGS. 7A-7G are cross-sectional illustrations depicting a process for assembling a multi-die system with hybrid bonding between dies using a carrier with a debond film that is released with an IR laser, in accordance with an embodiment.

FIGS. 8A and 8B are cross-sectional illustrations of an edge of a carrier substrate that shows issues with releasing a debond film when the debond film wraps around an edge of the carrier substrate, in accordance with an embodiment.

FIGS. 9A and 9B are cross-sectional illustrations that depict a carrier substrate with a debond film that wraps around an edge of the carrier substrate and creates issues with releasing the debond film, in accordance with an embodiment.

FIGS. 10A-10C are cross-sectional illustrations of a carrier substrate that is treated with an edge etching process to improve the release performance of the debond film, in accordance with an embodiment.

FIG. 11 is a schematic of a computing device built in accordance with an embodiment.

### EMBODIMENTS OF THE PRESENT DISCLOSURE

Described herein are electronic systems, and more particularly to die complexes that are fabricated through the use of a laser debonding process, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

Future scaling to higher density routing layers and interconnects, has led to an interest in silicon based carriers. Compared to glass-based carriers, silicon carriers offer a lower total thickness variation (TTV), better geometric stability, and compatibility with all silicon wafer handling tools and processes. Further, elimination of the organic adhesive and release layers allows for improved TTV at the point of the adhesive. Improved release layer design can also provide improved thermal and/or mechanical stability that leads to opportunities for high density 2.5D and 3D integration.

More generally, embodiments disclosed herein include the use of a release layer (also referred to herein as a debond film or a debond layer), that is sensitive to infrared (IR) radiation. In some embodiments, the debond film absorbs the IR radiation so that the debond film is ablated. This allows for the overlying structure (e.g., interposer, wafer, die complex, etc.) to be released. Silicon wafers are transparent to IR radiation, so the laser can be directed to the debond film through the thickness of the silicon carrier wafer. IR radiation may refer to radiation with a wavelength between approximately 800 nm and approximately 1.0 mm. In a particular embodiment, the IR radiation may have a wavelength between approximately 1.0 μm and approximately 10 μm, or between approximately 1.0 μm and approximately 20 μm. As used herein, “approximately” may refer to a range of values that are within ten percent of the stated value. For example, approximately 10 μm may refer to a range between 9 μm and 11 μm.

In an embodiment, the debond film may have a material composition suitable for deposition with a well-controlled deposition process, such as physical vapor deposition (PVD), atomic layer deposition (ALD), or chemical vapor deposition (CVD). These deposition processes may enable the formation of thin and low TTV materials. Between the low TTV of the silicon carrier and the low TTV of the debond film, a total TTV of the carrier system may be approximately 5 μm or less, or approximately 1 μm or less. In an embodiment, the debond film may have a thickness that is up to approximately 50 nm, up to approximately 20 nm, or up to approximately 10 nm. The debond film may have a single layer composition, or a multi-layer composition (as will be described in greater detail below). In the case of multi-layer approaches, the total thickness of all layers of the debond film may be up to approximately 500 nm, up to approximately 600 nm, or up to approximately 1,000 nm. Though, thicker debond films may also be used in some embodiments.

The debond film and silicon carrier wafer combination have benefits in addition to improved TTV, improved thermal stability, and improved mechanical stability. For example, costs of assembly can be reduced through the reuse of the silicon carrier wafers. In some instances, a cleaning process (e.g., an etching process) can be used to remove any residual material. A new debond film can then be deposited over the cleaned carrier substrate.

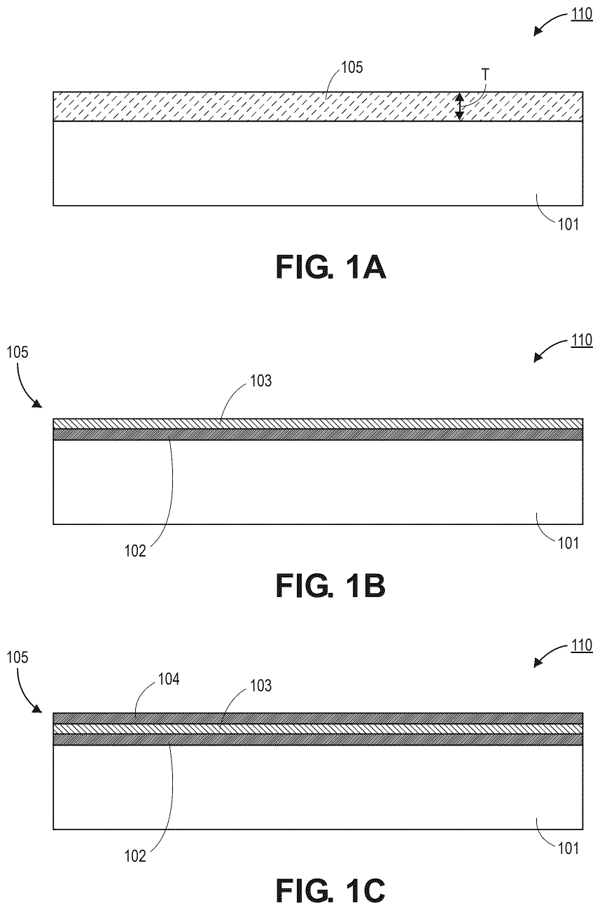

Referring now to FIG. 1A, a cross-sectional illustration of a carrier 110 is shown, in accordance with an embodiment. In an embodiment, the carrier 110 comprises a substrate 101 and a debond film 105 over the substrate 101. In an embodiment, the substrate 101 may have a wafer form factor. For example, a diameter of the substrate 101 may be approximately 200 mm, approximately 300 mm, or approximately 450 mm. Though, other wafer sizes may also be used in some embodiments.

In an embodiment, the substrate 101 comprises a silicon substrate. The silicon substrate 101 may be a high purity silicon material with a low dopant concentration (or substantially no dopants). In an embodiment, the silicon substrate 101 may have a thermal oxide (not shown). The silicon substrate 101 may have any suitable crystal orientation. For example, substrate 101 may have a (100) crystal orientation, a (111) crystal orientation, or a (110) crystal orientation. In an embodiment, the substrate 101 is a material that is substantially transparent to IR radiation. For example, IR radiation between approximately 1 μm and approximately 20 μm may pass through the substrate 101 without significant absorption of the IR radiation. Silicon substrates 101 satisfy this parameter in many embodiments. While silicon may be one example of a suitable substrate 101, other materials that are at least partially transparent to IR radiation may also be used in some embodiments. For example, the substrate 101 may also comprise germanium, sapphire, or silicon and carbon (e.g., silicon carbide), or glass. As used herein, “partially transparent to IR radiation” may refer to a material that absorbs up to 75% of the IR radiation that passes through the material, absorbs up to 25% of the IR radiation that passes through the material, absorbs up to 10% of the IR radiation that passes through the material, absorbs up to 5% of the IR radiation that passes through the material, or absorbs up to 1% of the IR radiation that passes through the material.

In an embodiment, the debond film 105 is provided over a top surface of the substrate 101. The debond film 105 may be a material that is configured to absorb the IR radiation that passes through the substrate 101 during a debonding process. In an embodiment, the debond film 105 may have a thickness T. The thickness T may be up to approximately 500 nm, up to approximately 100 nm, up to approximately 50 nm, up to approximately 20 nm, or up to approximately 10 nm. Though, larger thicknesses T may also be used in some embodiments. For example, the thickness T may be up to approximately 5 μm or greater in some embodiments.

In an embodiment, the debond film 105 may be deposited with a blanket deposition process. That is, the debond film 105 may be substantially uniform (with respect to thickness and material composition) across the surface of the substrate 101. For example, deposition processes may comprise PVD, CVD, ALD, and/or the like. In an embodiment, the combination of the debond film 105 and the substrate 101 may have a TTV that is approximately 5 μm or less, or approximately 1 μm or less.

In an embodiment, the debond film 105 may comprise a material (or materials) that are tuned for absorbing the IR radiation. In an embodiment, the debond film 105 may comprise an inorganic material. For example, the debond film 105 may comprise a thin metal layer or multiple metal layers (e.g., aluminum (Al), tungsten (W), copper (Cu), tantalum (Ta), titanium (Ti), molybdenum, (Mo), manganese (Mn), hafnium (Hf), chromium (Cr), niobium (Nb), zirconium (Zr), palladium (Pd), platinum (Pt), gold (Au), silver (Ag), ruthenium (Ru), tantalum nitride (TaN), titanium nitride (TiN), niobium nitride (NbN), chromium nitride (CrN),hafnium nitride (HfN), zirconium nitride (ZrN)). In some embodiments, the debond film 105 may additionally or alternatively include one or more layers of dielectric materials (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅), hafnium oxide (HfO₂), or zirconium oxide (ZrO₂)), which may be used to buffer laser ablation and thermal energy, or control thin film interference or adhesion. Thus, in some embodiments, the release layer(s) may be made of one or more materials that include elements such as aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), ruthenium (Ru), silicon (Si), oxygen (O), nitrogen (N), hydrogen (H), and carbon (C), including, without limitation, any of the materials referenced above.

In the illustrated embodiment of FIG. 1A, the debond film 105 is shown as a single layer. However, it is to be appreciated that the debond film 105 may comprise two or more layers. For example, the multiple layers may comprise absorption layers, transmission layers, and reflection layers. The reflection layers may reflect IR radiation back to the absorption layers through transmission layers in order to improve ablation of the debond film 105 during the laser release process. Examples of such multi-layer debond films 105 are shown in FIGS. 1B and 1C.

Referring now to FIG. 1B, a cross-sectional illustration of a carrier 110 is shown, in accordance with an additional embodiment. In an embodiment, the carrier 110 in FIG. 1B may be similar to the carrier 110 in FIG. 1A, with the exception of the construction of the debond film 105. For example, the debond film 105 may comprise a multi-layer stack, such as one with a first layer 102 and a second layer 103 over the first layer. In an embodiment, the first layer 102 may be an inorganic material that is configured to absorb the IR radiation from a laser release process. The second layer 103 may be a layer configured to reflect a significant portion of the IR radiation. The reflected IR radiation is directed back to the first layer 102, in order to improve the absorption (and ablation) of the first layer 102. As such, the release process is made more efficient.

In an embodiment, the first layer 102 may comprise a metallic layer (e.g., aluminum (Al), tungsten (W), copper (Cu), tantalum (Ta), titanium (Ti), molybdenum, (Mo), manganese (Mn), hafnium (Hf), chromium (Cr), niobium (Nb), zirconium (Zr), palladium (Pd), platinum (Pt), gold (Au), silver (Ag), ruthenium (Ru), tantalum nitride (TaN), titanium nitride (TiN), niobium nitride (NbN), chromium nitride (CrN),hafnium nitride (HfN), or zirconium nitride (ZrN)). In an embodiment, the second layer 103 may comprise a dielectric, such as silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅), hafnium oxide (HfO₂), or zirconium oxide (ZrO₂))).

In an embodiment, the thickness of the first layer 102 may be different than a thickness of the second layer 103. In an embodiment, the first layer 102 may be thinner than the second layer 103. Making the first layer 102 thinner allows for easier ablation of the first layer 102.

Referring now to FIG. 1C, a cross-sectional illustration of a carrier 110 is shown, in accordance with an additional embodiment. In an embodiment, the carrier 110 in FIG. 1C is similar to the carrier 110 in FIG. 1B, with the exception of the debond film 105. Instead of two layers 102 and 103, a set of three layers (i.e., a first layer 102, a second layer 103, and a third layer 104) are provided. In an embodiment, the first layer 102 may be an inorganic material that is configured to absorb the IR radiation from a laser release process. The second layer 103 may be a layer configured to reflect a significant portion of the IR radiation and transmit a significant portion of the IR radiation. The reflected IR radiation is directed back to the first layer 102. The third layer 104 may be configured to reflect a significant portion of the IR radiation back to the first layer 102, in order to improve the absorption (and ablation) of the first layer 102. As such, the release process is made more efficient. In an embodiment, the third layer 104 may also be configured to prevent transmission of a significant portion of the IR radiation. While examples of a two layer debond film 105 (FIG. 1B) and a three layer debond film 105 (FIG. 1C) are shown, it is to be appreciated that the debond film 105 can comprise any number of layers, including layers below the first layer 102 and/or above the third layer 104 in FIG. 1C.

In one embodiment, the first layer 102 and the fourth layer 104 may be similar to each other (as indicated by the shading). Though, in other embodiments, the first layer 102 may be different than the fourth layer 104. In an embodiment, the compositions, thicknesses, order, etc. of the various layers may be chosen in order to optimize the ablation of at least a portion of the debond film 105, and reduce or prevent transmission through the debond film 105. For example, multiple layers of the debond film 105 may be used to buffer laser ablation and thermal energy, control thin film interference between layers, and/or to improve adhesion between the carrier 110 and a subsequently added structure (not shown in FIGS. 1A-1C).

The use of such carriers 110 is particularly beneficial when fusion bonding and hybrid bonding processes are implemented in the overlying structure. Fusion bonding processes result in the fusion of planar surfaces to form a mechanical bond, often using dielectric layers. Hybrid bonding processes result in the fusion of opposing metallic and dielectric surfaces in order to form an electrical and mechanical bond that does not require solder or the like. In a hybrid bonding process, the metallic contact surfaces are provided in a dielectric layer so that the metallic surfaces are slightly recessed below a surface of the dielectric layer. During the hybrid bonding, the opposing dielectric surfaces are brought together and bond with each other weakly via Van der Waals forces (i.e., dielectric-to-dielectric bonding). In a subsequent anneal step, the recessed metallic contacts expand such that the metallic surfaces make contact and bond (i.e., metal-to-metal bonding).

The viability of a fusion bonding and/or hybrid bonding process is particularly vulnerable to non-planar surfaces. That is, when the TTV is high, it becomes more difficult to implement such bonding. Accordingly, carriers 110 such as those described herein may be beneficial for enhancing these types of bonding processes. Further, the use of fusion bonding and/or hybrid bonding allows for finer pitch interconnects. This allows for higher density connections between components (e.g., dies) and enables enhanced integration of complex die complexes and/or the like.

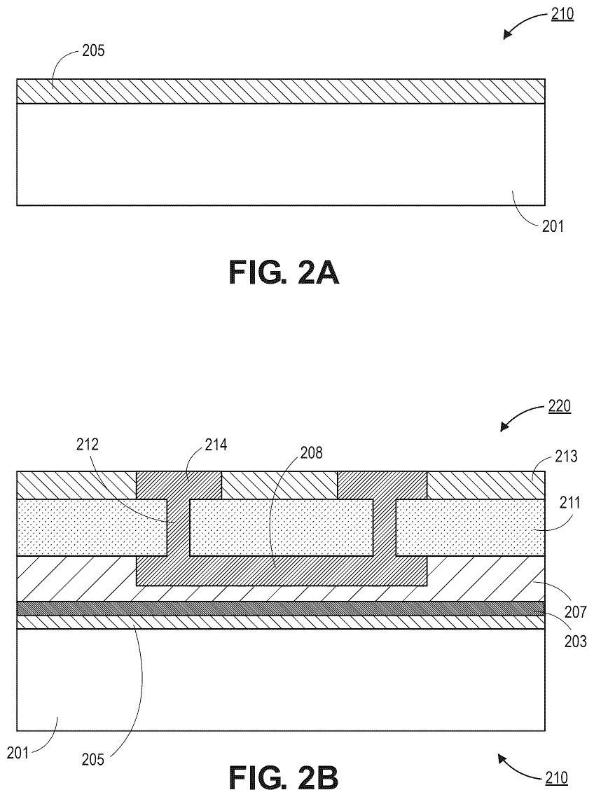

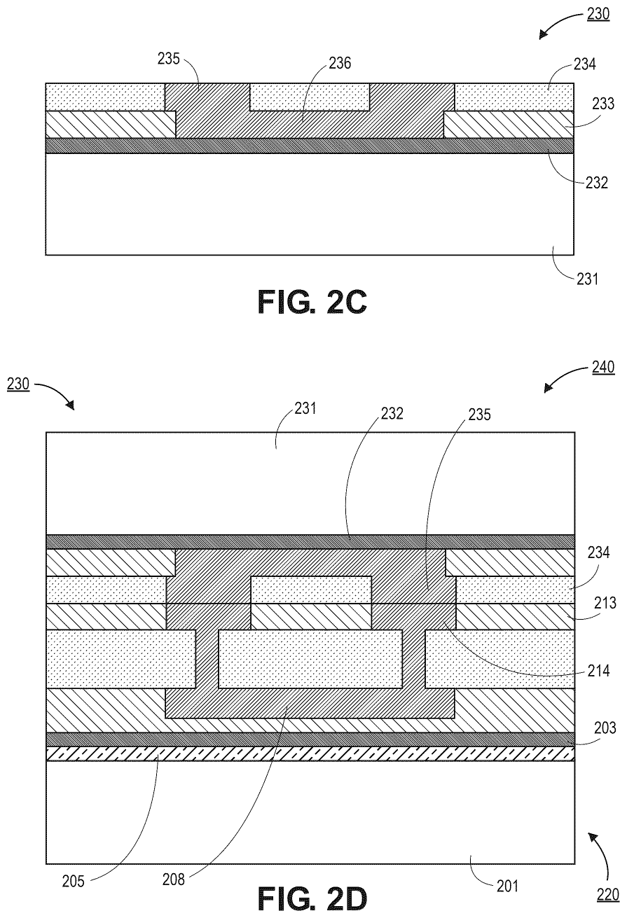

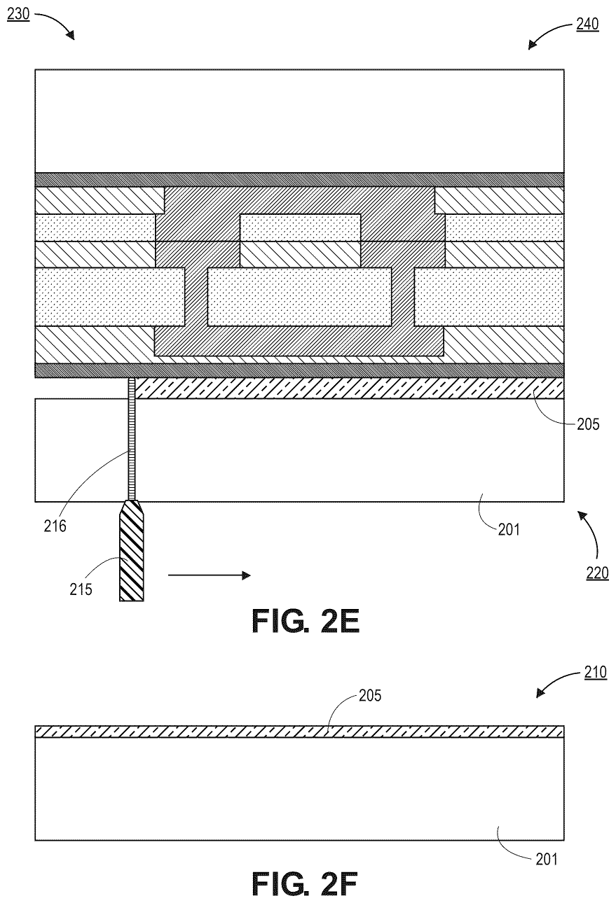

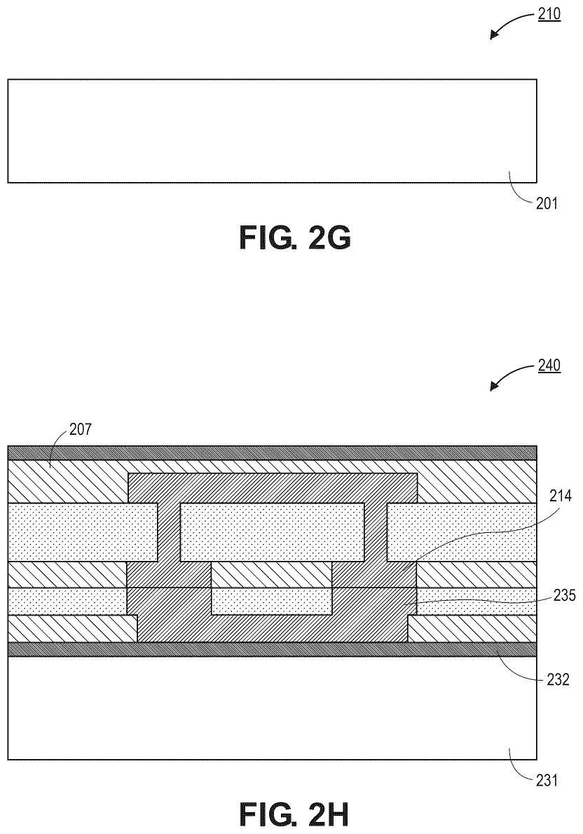

Referring now to FIGS. 2A-2H, a series of cross-sectional illustrations depicting a process for hybrid bonding a first pad to a second pad through the use of a carrier is shown, in accordance with an embodiment. The carrier may include a debond film that is released through the use of IR laser exposure.

Referring now to FIG. 2A, a cross-sectional illustration of a carrier 210 is shown, in accordance with an embodiment. In an embodiment, the carrier 210 may be similar to any of the carriers described in greater detail herein. For example, the carrier 210 may comprise a substrate 201 that is at least partially transparent to IR radiation (e.g., a silicon substrate 201) and a debond film 205 that absorbs IR radiation in order to ablate at least a portion of the debond film 205. The debond film 205 may be similar to the debond films 105 described in greater detail herein. That is, the debond film 205 may include any number of layers. Further, any debond films described herein may include multiple layer configurations such as those described with respect to FIGS. 1B and 1C.

Referring now to FIG. 2B, a cross-sectional illustration of a device 220 that is built up on the carrier 210 is shown, in accordance with an embodiment. In an embodiment, a device layer 203 and a dielectric layer 207 may be provided over the debond film 205. The dielectric layer 207 may be an adhesive dielectric material in order to improve mechanical coupling within the device 220. In some embodiments, the dielectric layer 207 may be considered as being part of the debond film 205 (e.g., when the debond film 205 has a multi-layer construction). In an embodiment, a trace 208 may be provided on and/or embedded in the dielectric layer 207. The trace 208 may comprise an electrically conductive material, such as copper or the like.

In an embodiment, first pads 214 may be provided above the trace 208. The first pads 214 may be electrical pads, such as pads comprising copper or the like. In an embodiment, the first pads 214 may be electrically coupled to the trace 208 by vias 212 that pass through an insulating layer 211. The insulating layer 211 may be electrically insulating material, such as an inorganic dielectric, a buildup film material, an epoxy, a mold layer, or the like. In an embodiment, a dielectric layer 213 may be provided over the insulating layer 211. The dielectric layer 213 may comprise a silicon dioxide material, a silicon nitride material, or any other suitable dielectric material. The dielectric layer 213 may have a top surface that is substantially coplanar to top surfaces of the first pads 214. Though, some amount of dishing (or other recessing) may be provided between the top surface of the dielectric layer 213 and the top surfaces of the first pads 214. The coplanar (or near coplanar) relationship between the first pads 214 and the dielectric layer 213 is useful for enabling high performance hybrid bonding processes.

Referring now to FIG. 2C, a cross-sectional illustration of a device wafer 230 is shown, in accordance with an embodiment. In an embodiment, the device wafer 230 may comprise a device substrate 231. The device substrate 231 may be a semiconductor substrate, such as a silicon substrate. In an embodiment, a device layer 232 is provided on the device substrate 231. The device layer 232 may comprise one or more active and/or passive electrical components. For example, the device layer 232 may comprise one or more of a transistor, an inductor, a capacitor, a resistor, and/or the like. The device layer 232 may also comprise electrical routing (e.g., traces, vias, pads, etc.) in order to electrically couple components together. The components and routing within the device layer 232 are omitted for simplicity.

In an embodiment, a dielectric layer 233 may be provided over the device layer 232, and a trace 236 may be provided in the dielectric layer 233. Second pads 235 may be provided over the trace 236 in a dielectric layer 234. The second pads 235 may be directly connected to the trace 236, or vias (not shown) may electrically couple the second pads 235 to the trace 236. The second pads 235 may be electrically conductive pads, such as pads comprising copper or the like. In an embodiment, top surfaces of the second pads 235 are substantially coplanar with a top surface of the dielectric layer 234. Though, some amount of dishing or recessing may be present between the top surfaces of the second pads and the top surface of the dielectric layer 234.

Referring now to FIG. 2D, a cross-sectional illustration of an assembly 240 after the device wafer 230 is mounted to the device 220 is shown, in accordance with an embodiment. In an embodiment, the device 220 and the device wafer 230 may be mounted together with a hybrid bonding process. That is, the first pads 214 may be fusion bonded to the second pads 235. Additionally, the dielectric layer 213 may be directly bonded to the dielectric layer 234. That is, there may not be a solder or any other intervening material between the first pads 214 and the second pads 235. In an embodiment, the hybrid bonding process is improved due to the low TTV provided by the use of the carrier 210.

In an embodiment, the assembly 240 shown has a single layer of traces and vias on each side of the assembly 240. However, it is to be appreciated that there may be multiple layers of traces and/or vias on either side of the assembly 240 in order to provide the necessary routing. For example, electrical routing may provide electrical coupling between the device layer 203 and the device layer 232 in some embodiments.

Referring now to FIG. 2E, a cross-sectional illustration of the assembly 240 during a laser release process is shown, in accordance with an embodiment. In an embodiment, an IR laser 215 is scanned across the back of the assembly 240 so that IR radiation 216 passes through the substrate 201 and is absorbed by the debond film 205. The absorbed IR radiation 216 heats up the debond film 205 and ablates at least a portion of the debond film 205. After the laser 215 treatment, the substrate 201 may be removed.

Referring now to FIG. 2F, a cross-sectional illustration of the removed carrier 210 is shown, in accordance with an embodiment. In an embodiment, the carrier 210 may have a residual portion of the debond film 205 left on the surface of the substrate 201. This excess debond film 205 may be removed with an etching process or the like. A pristine substrate 201 after cleaning is shown in FIG. 2G. At this point, a new debond film 205 can be applied to the substrate 201, and the carrier 210 can be reused.

Referring now to FIG. 2H, a cross-sectional illustration of the assembly 240 after debonding is shown, in accordance with an embodiment. As shown, the assembly 240 maintains the device substrate 231 with overlying hybrid bonded structures (e.g., first pads 214 and second pads 235). The dielectric layer 207 may also remain over the electrical structures in some embodiments. In an embodiment, the process shown in FIGS. 2A-2H may be repeated any number of times in order to connect other devices with additional carrier wafers with an IR debond film and hybrid bonding layers.

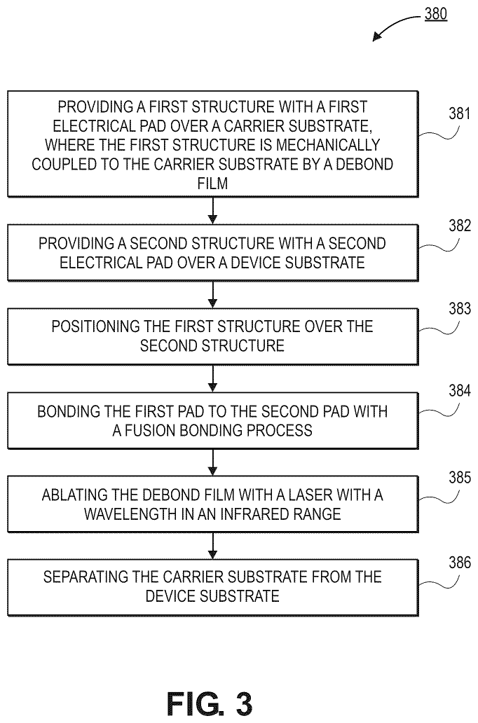

Referring now to FIG. 3, a process flow diagram of a process 380 for bonding components together with a fusion bonding process while supported by a carrier with a debond film is shown, in accordance with an embodiment. In an embodiment, the process 380 may begin with operation 381, which comprises providing a first structure with a first electrical pad over a carrier substrate. In an embodiment, the first structure may be mechanically coupled to the carrier substrate by a debond film. In an embodiment, the carrier substrate may be a substrate that is at least partially transparent to IR radiation, and the debond film may be an inorganic material capable of absorbing the IR radiation. For example, the substrate may be a silicon substrate, and the debond film may be a metallic layer.

In an embodiment, the process 380 may continue with operation 382, which comprises providing a second structure with a second electrical pad over a device substrate. In an embodiment, the device substrate may comprise a semiconductor substrate with a device layer. The device layer may comprise active and/or passive electrical components (e.g., transistors, inductors, capacitors, resistors, etc.). In an embodiment, the second electrical pad may be provided in a dielectric layer over the device layer.

In an embodiment, the process 380 may continue with operation 383, which comprises positioning the first structure over the second structure. The first structure and the second structure may be positioned so that the first electrical pad and the second electrical pad are directly contacting each other.

In an embodiment, the process 380 may continue with operation 384, which comprises bonding the first pad to the second pad with a fusion bonding process. In an embodiment, the fusion bonding process allows for the first electrical pad and the second electrical pad to undergo an interdiffusion process in order to form a single continuous electrical pad. That is, the first electrical pad and the second electrical pad may be electrically coupled to each other without any intervening material (such as a solder or the like). In some embodiments, the fusion bonding process may also include a hybrid bonding operation. Hybrid bonding may refer to a process where the electrical pads are diffusion bonded to each other, while dielectric layers adjacent to the pads are fusion bonded together, similar to embodiments described in greater detail herein.

In an embodiment, the process 380 may continue with operation 385, which comprises ablating the debond film with a laser with a wavelength in an infrared range. In an embodiment, the debond film is at least partially ablated so that the carrier substrate can be detached from the first structure and the second structure. The laser IR radiation may pass through a thickness of the carrier substrate and be absorbed by the debond film. Scanning the laser across the carrier substrate allows for the removal of the debond film.

In an embodiment, the process 380 may continue with operation 386, which comprises separating the carrier substrate from the device substrate. The carrier substrate may be removed by lifting up the device substrate since the debond film that holds the carrier substrate and the device substrate together has been removed. After removal of the carrier substrate, the device substrate may be singulated or otherwise processed to prepare for integration into a larger electrical system.

In the embodiments described in greater detail above, the fusion bonding process is shown generically between a pair of pads. That is, the complexities of the structures and integration of components (e.g., dies) is omitted for simplicity. However, it is to be appreciated that fusion bonding and/or hybrid bonding is particularly useful when constructing or assembling die complexes with a plurality of dies. This allows for compact structures with a larger number of interconnects between components. The following process flows provide some examples of such structures.

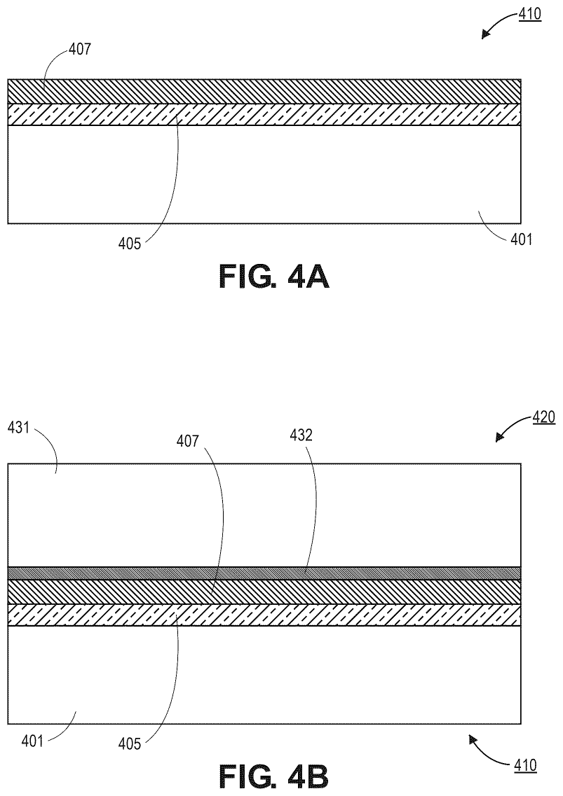

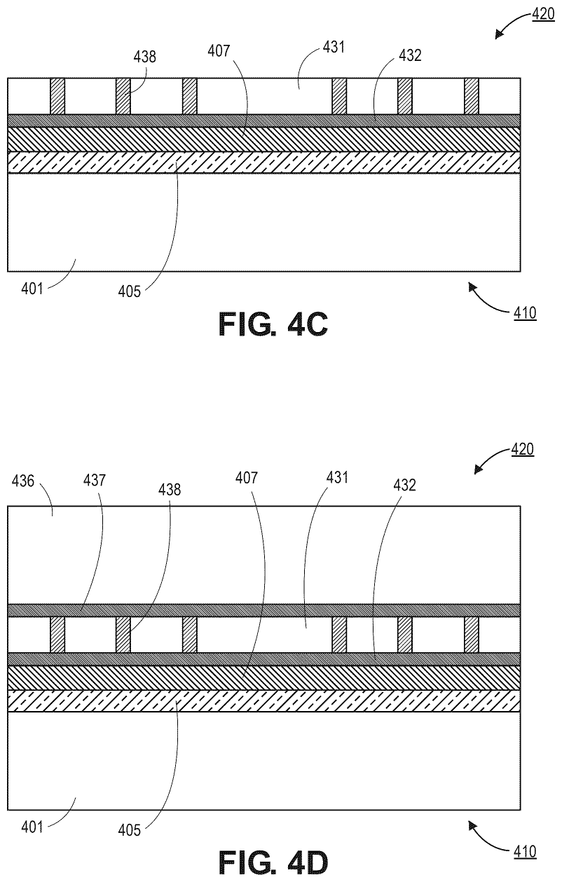

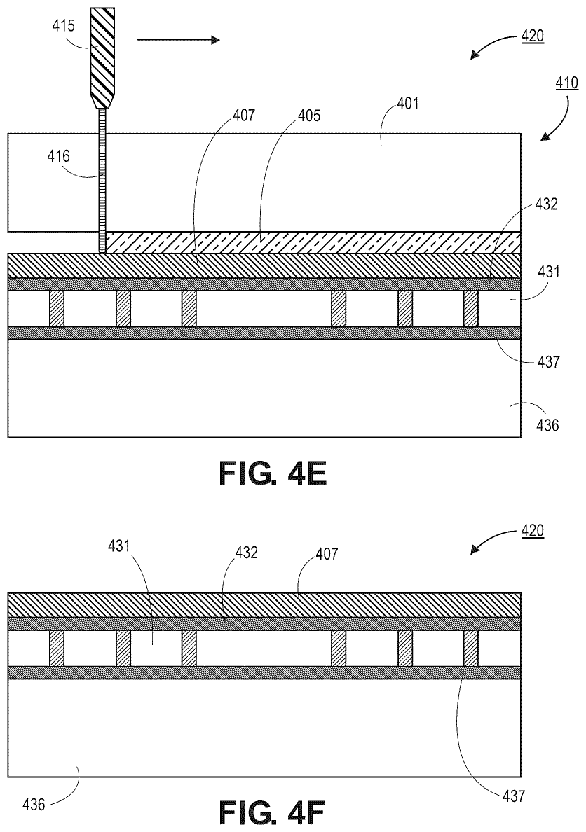

Referring now to FIGS. 4A-4F, a series of cross-sectional illustrations depicting a process for stacking multiple device wafers in a stack is shown, in accordance with an embodiment. Such a process may sometimes be referred to as being a wafer bonding process.

Referring now to FIG. 4A, a cross-sectional illustration of a carrier 410 is shown, in accordance with an embodiment. In an embodiment, the carrier 410 may be similar to any of the carriers described in greater detail herein. For example, the carrier 410 may comprise a substrate 401 that is at least partially transparent to IR radiation (e.g., a silicon substrate 401) and a debond film 405 that absorbs IR radiation in order to ablate at least a portion of the debond film 405. The debond film 405 may be similar to any of the debond films described in greater detail herein. In an embodiment, a dielectric or bonding layer 407 may be provided over the debond film 405.

Referring now to FIG. 4B, a cross-sectional illustration of a device 420 is shown, in accordance with an embodiment. In an embodiment, the device 420 may comprise a first device substrate 431 that is attached to the bonding layer 407. In an embodiment, a first device layer 432 may be provided on the first device substrate 431. The first device layer 432 may comprise active and/or passive components (e.g., transistors, capacitors, inductors, resistors, etc.).

Referring now to FIG. 4C, a cross-sectional illustration of the device 420 after the first device substrate 431 is recessed and vias 438 are formed through a thickness of the first device substrate 431 is shown, in accordance with an embodiment. The first device substrate 431 may be recessed with a planarizing process, such as a chemical-mechanical planarization (CMP) process or the like. Via openings can then be formed with an etching process, and a metal deposition process can be used to form electrically conductive vias 438 in the via openings.

Referring now to FIG. 4D, a cross-sectional illustration of the device 420 after a second device substrate 436 is adhered to the first device substrate 431. The second device substrate 436 may include a second device layer 437. The second device layer 437 may comprise active and/or passive components (e.g., transistors, capacitors, inductors, resistors, etc.). In an embodiment, the vias 438 may electrically couple the first device layer 432 to the second device layer 437. In some embodiments, the vias 438 are fusion bonded to electrical features within the second device layer 437. In some instances, the vias 438 are separated from the second device layer 437 by a hybrid bonding layer (not shown). The hybrid bonding layer may comprise electrical pads that are surrounded by a dielectric layer. The electrical pads may be diffusion bonded to the vias 438 in some embodiments.

Referring now to FIG. 4E, a cross-sectional illustration of the device 420 during a carrier 410 release process is shown, in accordance with an embodiment. As shown, a laser 415 exposes the debond film 405 with IR radiation 416 that passes through a thickness of the substrate 401. As the laser 415 scans across the substrate 401, the debond film 405 is removed through ablation. This releases the remaining portion of the device 420.

Referring now to FIG. 4F, a cross-sectional illustration of the device 420 after release from the carrier 410 is shown, in accordance with an embodiment. As shown, the bonding layer 407 (or a portion of the bonding layer 407) may remain over the first device layer 432. Though, in other embodiments, the bonding layer 407 may be removed. Buildup layers, routing layers, and/or the like can be added over the device 420 in some embodiments. In an embodiment, the device 420 may be singulated after removal of the carrier 410.

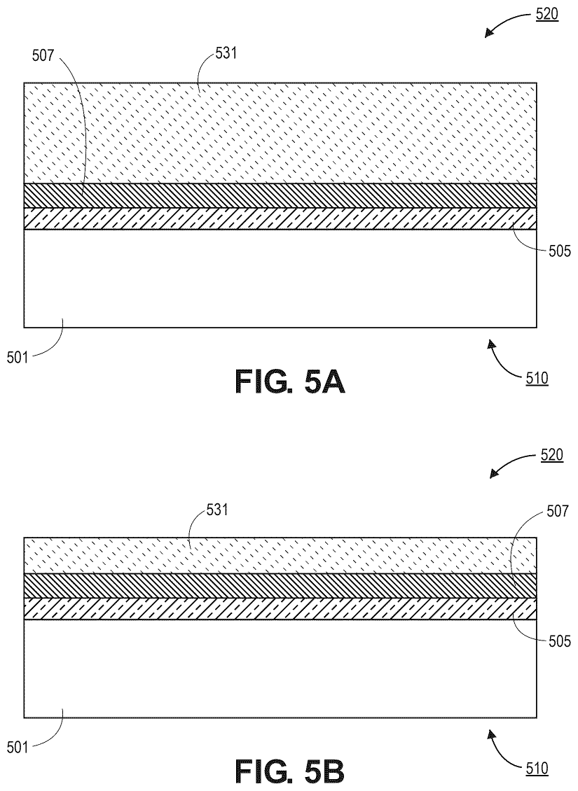

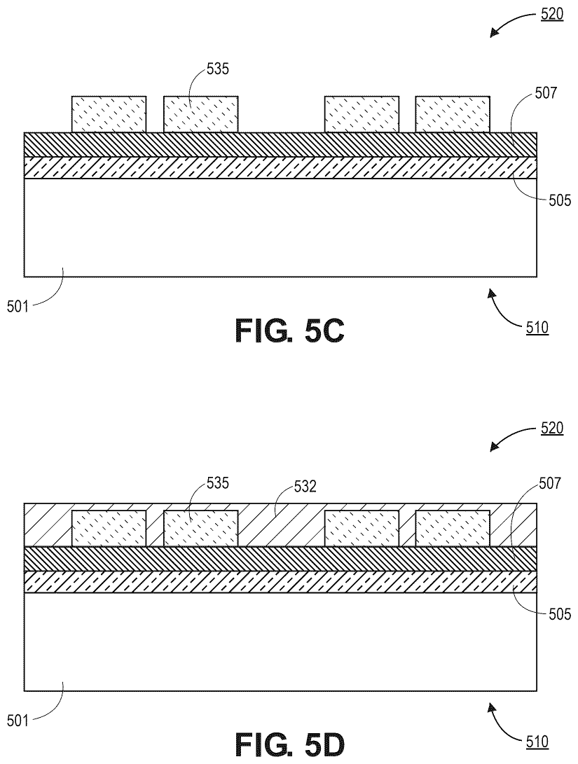

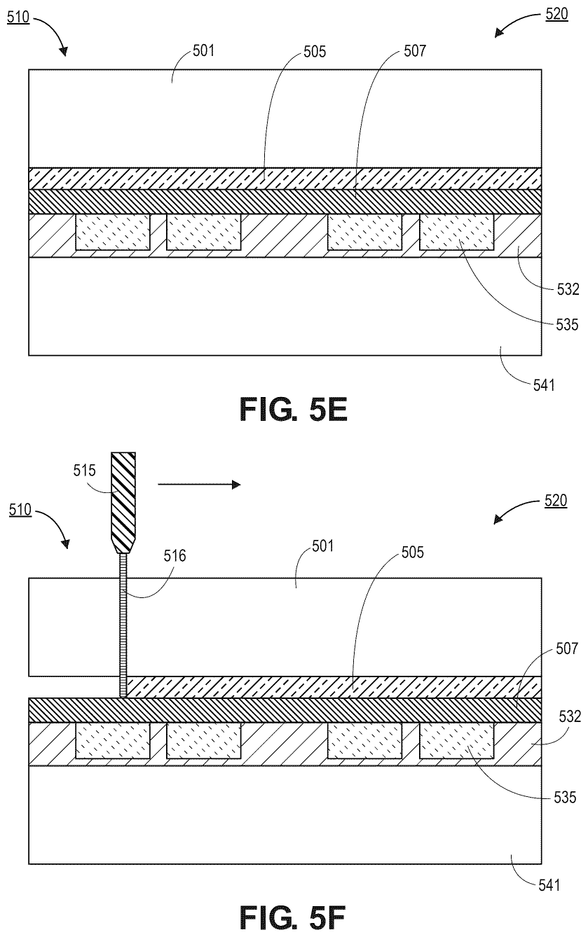

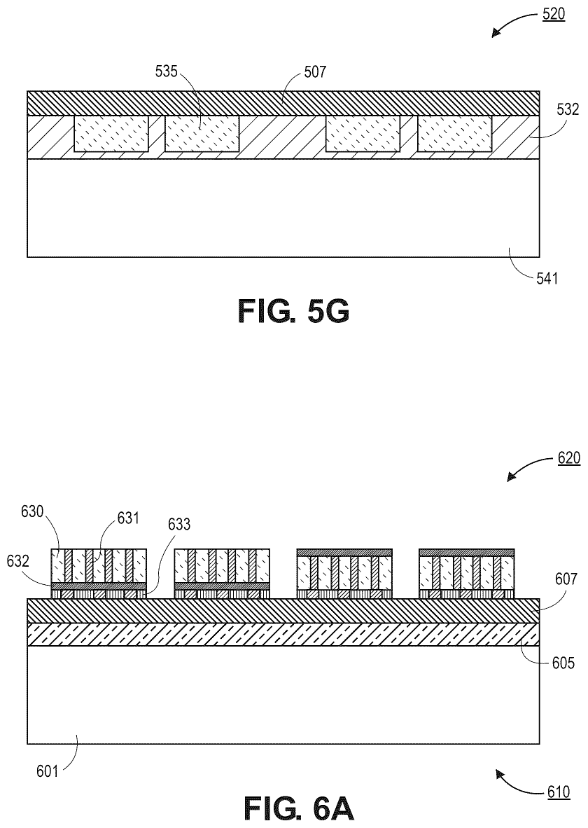

Referring now to FIGS. 5A-5G, a series of cross-sectional illustrations depicting a process of forming a multi-die complex on a carrier 510 using a plasma dicing process is shown, in accordance with an embodiment.

Referring now to FIG. 5A, a cross-sectional illustration of a device 520 is shown, in accordance with an embodiment. In an embodiment, the device 520 may comprise a carrier 510. In an embodiment, the carrier 510 may be similar to any of the carriers described in greater detail herein. For example, the carrier 510 may comprise a substrate 501 that is at least partially transparent to IR radiation (e.g., a silicon substrate 501) and a debond film 505 that absorbs IR radiation in order to ablate at least a portion of the debond film 505. The debond film 505 may be similar to any of the debond films described in greater detail herein. In an embodiment, a dielectric bonding layer 507 may be provided over the debond film 505. A device wafer 531 may be attached to the bonding layer 507 with a wafer-to-wafer bonding process. The device wafer 531 may be a semiconductor wafer, such as a silicon wafer.

Referring now to FIG. 5B, a cross-sectional illustration of the device 520 after a wafer thinning process is shown, in accordance with an embodiment. In an embodiment, the wafer thinning process may reduce a thickness of the device wafer 531. For example, the thinning process may use a CMP process or the like.

Referring now to FIG. 5C, a cross-sectional illustration of the device 520 after a dicing operation has been implemented in order to define a plurality of dies 535 from the larger device wafer 531. The dies 535 may be any type of die, such as a processor (e.g., a central processing unit (CPU), a graphics processing unit (GPU), an XPU), a field programmable gate array (FPGA), an application specific integrated circuit (ASIC), a communications die, a memory die, and/or the like.

Referring now to FIG. 5D, a cross-sectional illustration of the device 520 after a dielectric layer 532 is applied over the dies 535. The dielectric layer 532 may be an oxide material, a nitride material, or the like. In an embodiment, the dielectric layer 532 may be deposited with any suitable deposition process (e.g., PVD, ALD, CVD, etc.). The deposited dielectric layer 532 may be planarized (e.g., with a CMP process) in order to provide a flat surface over the dies 535.

Referring now to FIG. 5E, a cross-sectional illustration of the device 520 after a receiving wafer 541 is attached to the dielectric layer 532 is shown, in accordance with an embodiment. In an embodiment, the receiving wafer 541 may be a silicon wafer or the like. The receiving wafer 541 may be bonded with a wafer bonding process.

Referring now to FIG. 5F, a cross-sectional illustration of the device 520 during a carrier 510 release process is shown, in accordance with an embodiment. As shown, a laser 515 exposes the debond film 505 with IR radiation 516 that passes through a thickness of the substrate 501. As the laser 515 scans across the substrate 501, the debond film 505 is removed through ablation. This releases the remaining portion of the device 520.

Referring now to FIG. 5G, a cross-sectional illustration of the device 520 after release from the carrier 510 is shown, in accordance with an embodiment. As shown, the bonding layer 507 (or a portion of the bonding layer 507) may remain over the dielectric layer 532 and the dies 535. Though, in other embodiments, the bonding layer 507 may be removed. Buildup layers, routing layers, and/or the like can be added over the device 520 in some embodiments. In an embodiment, the device 520 may be singulated after removal of the carrier 510. In other embodiments, another carrier wafer with additional layers or die may be bonded to the bonding layer 507. In other embodiments, the boding layer 507 or a hybrid-bonding layer (not shown) may be fabricated on the device 520 and another carrier wafer with a hybrid-bonding layer with devices or die may be bonded and electrically coupled to the device 520.

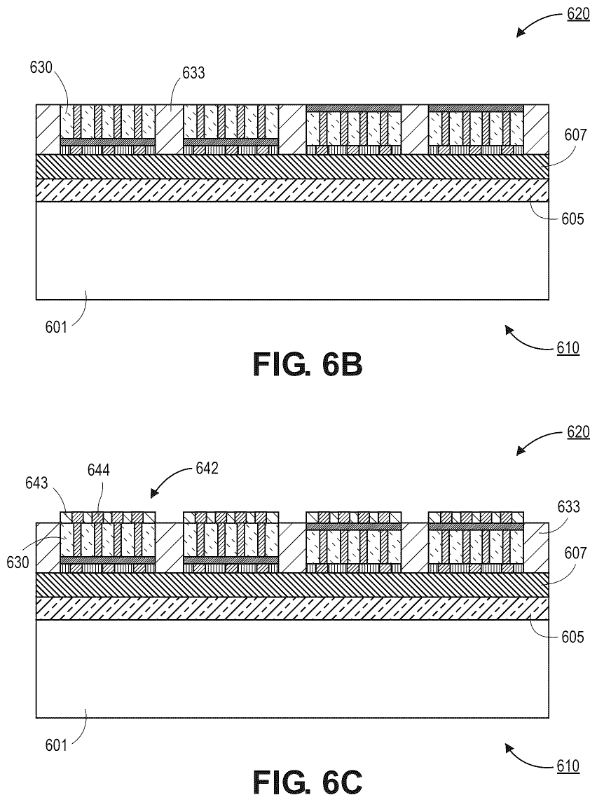

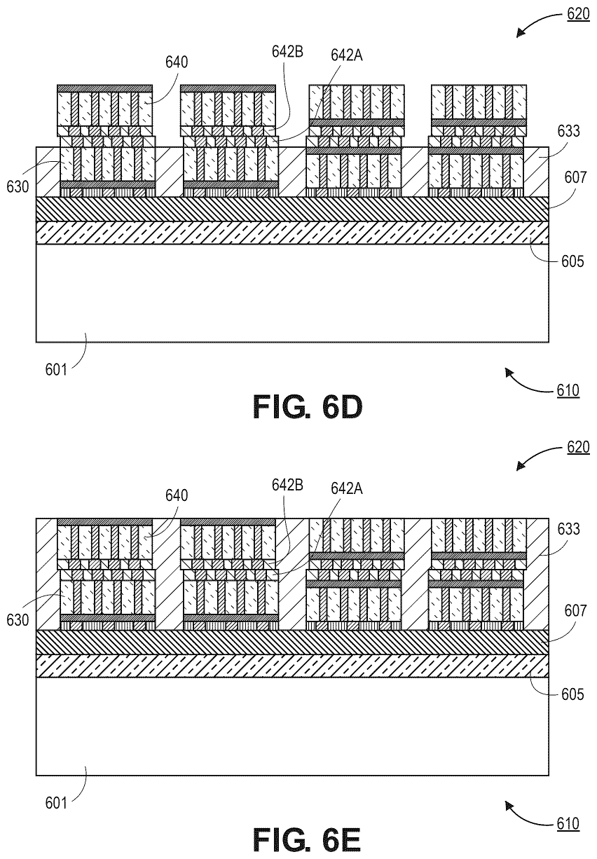

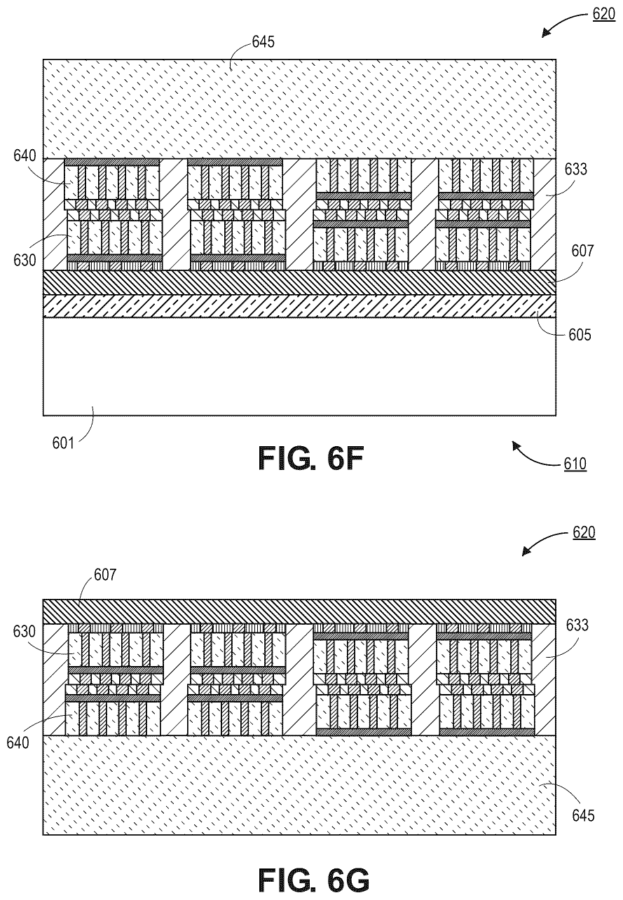

Referring now to FIGS. 6A-6G, a series of cross-sectional illustrations depicting a process for forming the multi-die complex through the use of a carrier 610 with a debond film 605 that is released with IR radiation is shown, in accordance with an embodiment. The low TTV of the carrier 610 allows for hybrid bonding between stacked dies of the multi-die complex.

Referring now to FIG. 6A, a cross-sectional illustration of a device 620 is shown, in accordance with an embodiment. In an embodiment, the device 620 may comprise a carrier 610. In an embodiment, the carrier 610 may be similar to any of the carriers described in greater detail herein. For example, the carrier 610 may comprise a substrate 601 that is at least partially transparent to IR radiation (e.g., a silicon substrate 601) and a debond film 605 that absorbs IR radiation in order to ablate at least a portion of the debond film 605. The debond film 605 may be similar to any of the debond films described in greater detail herein. In an embodiment, a dielectric bonding layer 607 may be provided over the debond film 605.

In an embodiment, a plurality of first dies 630 may be provided over the bonding layer 607. The first dies 630 may be placed on the bonding layer 607 with any suitable process, such as a pick-and-place process. Since completed dies are being integrated into the device 620, known good dies can be used. This increases the yield of the completed device 620. In an embodiment, the first dies 630 may comprise vias 631 (e.g., through silicon vias (TSVs)) and a device layer 632. The device layer may comprise active and/or passive components (e.g., transistors, capacitors, inductors, resistors, etc.). In an embodiment, an interconnect layer 633 is provided between the first dies 630 and the bonding layer 607. The interconnect layer 633 may comprise electrical interconnects that are surrounded by a dielectric material.

As shown in FIG. 6A, the first dies 630 may be placed on the carrier 610 with any orientation. For example, the two first dies 630 on the left are placed with a face down orientation (i.e., the device layer 632 faces the carrier 610), and the two first dies 630 on the right are placed with a face up orientation (i.e., the device layer 632 faces away from the carrier 610). In some embodiments, all dies 630 are placed face down, and thinned by backside grinding after bonding to the carrier 610. This enables thin die 630. In these embodiments, the TSVs 631 may be fabricated before or after they are bonded to the carrier substrate 610.

Referring now to FIG. 6B, a cross-sectional illustration of the device 620 after a dielectric layer 633 is provided around the first dies 630 is shown, in accordance with an embodiment. The dielectric layer 633 may be any suitable dielectric material, such as a buildup film, a molding material, an oxide, a nitride, and/or the like. In an embodiment, the dielectric layer 633 is planarized with a top surface of the first dies 630.

Referring now to FIG. 6C, a cross-sectional illustration of the device 620 after a first hybrid bonding interconnect (HBI) layer 642 is applied to each of the first dies 630 is shown, in accordance with an embodiment. The HBI layer 642 may comprise electrical pads 644 that are surrounded by a dielectric layer 643. The HBI layers 642 may be formed with any suitable patterning and/or deposition processes. In the illustrated embodiment, a discrete HBI layer 642 is provided over each first die 630. In other embodiments, a continuous HBI layer 642 may extend over two or more of the first dies 630.

Referring now to FIG. 6D, a cross-sectional illustration of the device 620 after second dies 640 are attached to the first dies 630 through a hybrid bonding process is shown, in accordance with an embodiment. In an embodiment, the second dies 640 may also include HBI layers 642. As such, HBI layer 642A of the first dies 630 can be hybrid bonded to HBI layer 642B of the second dies 640. As shown, there may be some amount of offset between the first dies 630 and the second dies 640 due to alignment tolerances of the assembly process.

In an embodiment, the second dies 640 may be similar to the first dies 630. Though, in other embodiments, first dies 630 and second dies 640 may be different from each other. The second dies 640 may also be attached to the device 620 with any suitable orientation (e.g., face up or face down). In some embodiments, all dies 640 are placed face down, and thinned by backside grinding after bonding to the HBI layers 642. This enables thin die 640. In these embodiments, the TSVs may be fabricated before or after they are bonded to the device 620.

Referring now to FIG. 6E, a cross-sectional illustration of the device 620 after the dielectric layer 633 is extended to cover the second dies 640 is shown, in accordance with an embodiment. The dielectric layer 633 may be added with any suitable process, such as a lamination process or the like.

Referring now to FIG. 6F, a cross-sectional illustration of the device 620 after a receiving wafer 645 is added is shown, in accordance with an embodiment. In an embodiment, the receiving wafer 645 may be a silicon wafer or the like. The receiving wafer 645 may be added with a wafer bonding process. In some embodiments, a hybrid bonding process may be used for at least part of the attachment of the receiving wafer 645 to the device 620.

Referring now to FIG. 6G, a cross-sectional illustration of the device 620 after the carrier 610 is removed is shown, in accordance with an embodiment. The carrier 610 may be removed with an IR radiation exposure process similar to any such processes described in greater detail herein. For example, an IR laser may expose the debond film through the carrier substrate. The carrier substrate can then be removed. In some embodiments, the bonding layer 607 may remain on the device 620.

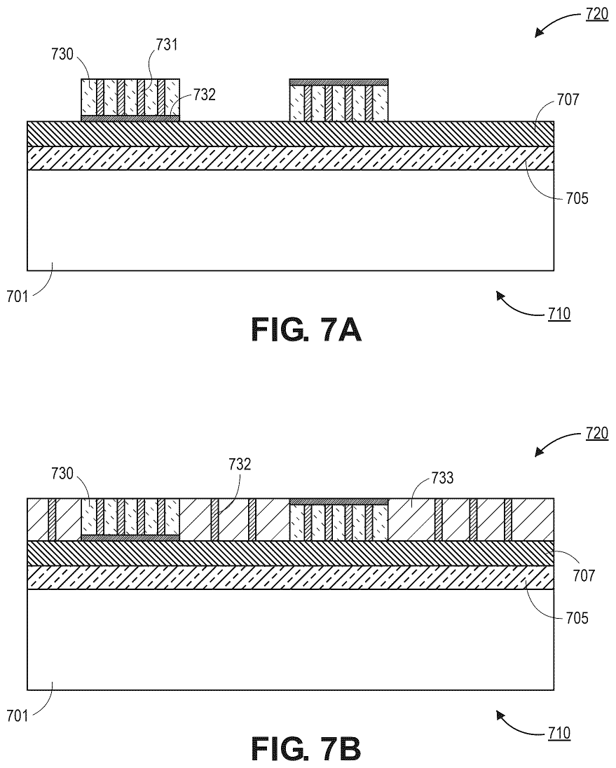

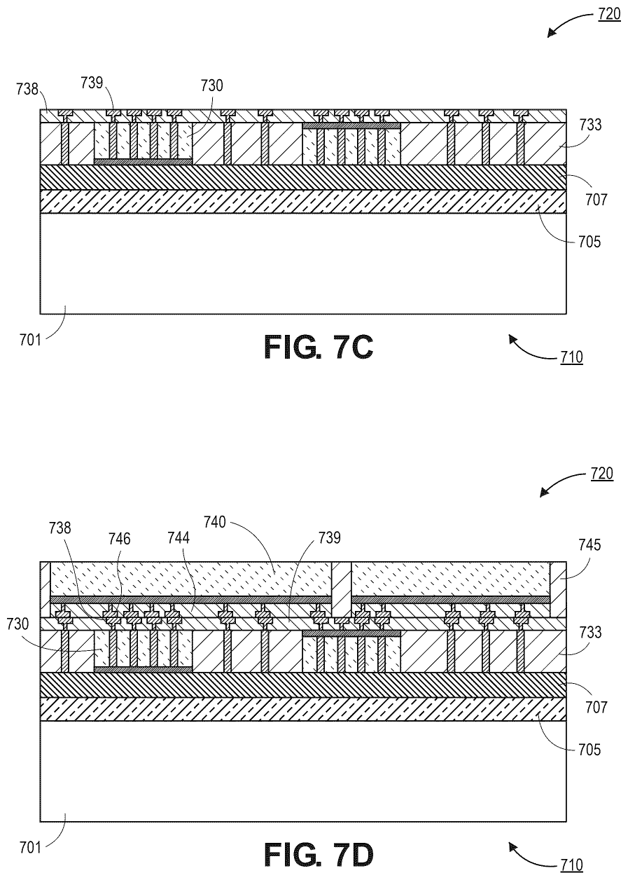

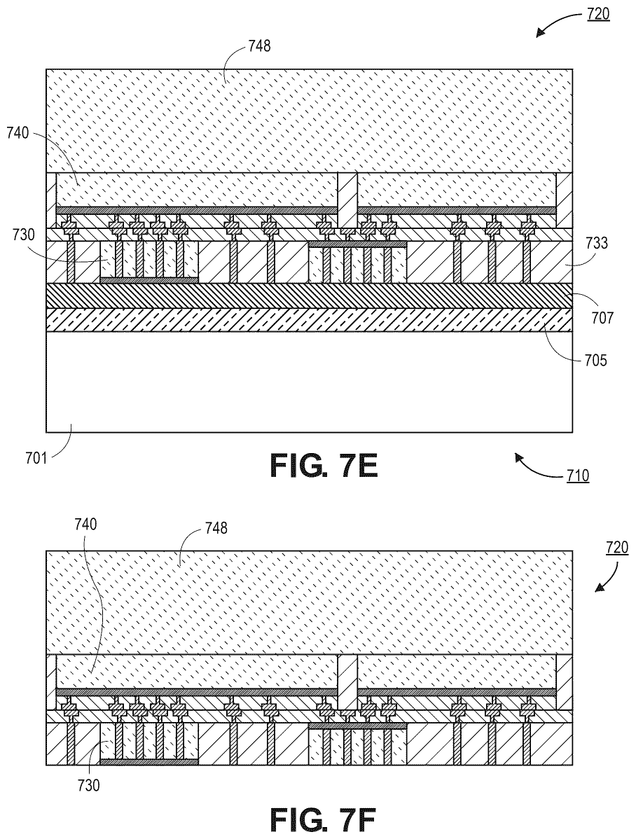

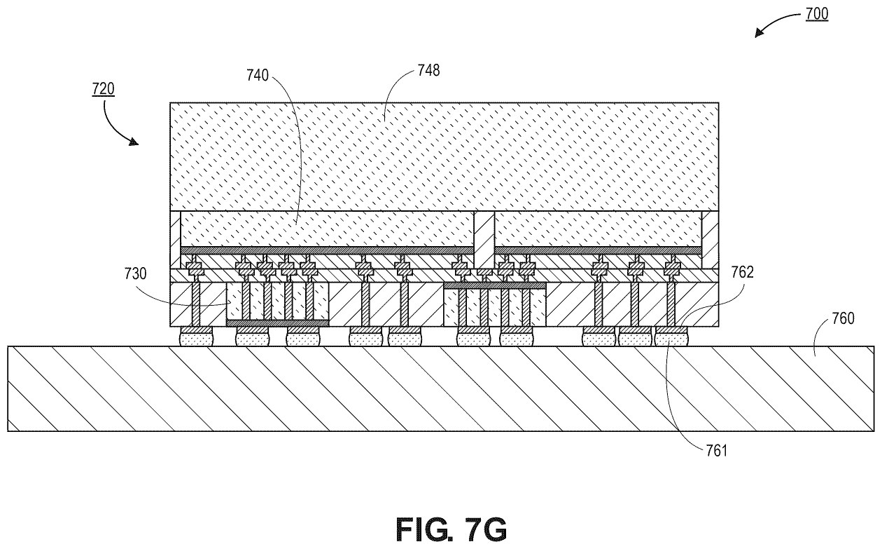

Referring now to FIGS. 7A-7G, a series of cross-sectional illustrations depicting a process for forming a multi-die complex with dies at different layers within the device 720 is shown, in accordance with an embodiment.

Referring now to FIG. 7A, a cross-sectional illustration of a device 720 is shown, in accordance with an embodiment. In an embodiment, the device 720 may comprise a carrier 710. In an embodiment, the carrier 710 may be similar to any of the carriers described in greater detail herein. For example, the carrier 710 may comprise a substrate 701 that is at least partially transparent to IR radiation (e.g., a silicon substrate 701) and a debond film 705 that absorbs IR radiation in order to ablate at least a portion of the debond film 705. The debond film 705 may be similar to any of the debond films described in greater detail herein. In an embodiment, a dielectric bonding layer 707 may be provided over the debond film 705.

In an embodiment, a plurality of first dies 730 may be provided over the bonding layer 707. The first dies 730 may be placed on the bonding layer 707 with any suitable process, such as a pick-and-place process. Since completed dies are being integrated into the device 720, known good dies can be used. This increases the yield of the completed device 720. In an embodiment, the first dies 730 may comprise vias 731 (e.g., TSVs) and a device layer 732. The device layer may comprise active and/or passive components (e.g., transistors, capacitors, inductors, resistors, etc.).

As shown in FIG. 7A, the first dies 730 may be placed on the carrier 710 with any orientation. For example, the first die 730 on the left is placed with a face down orientation (i.e., the device layer 732 faces the carrier 710), and the first die 730 on the right is placed with a face up orientation (i.e., the device layer 732 faces away from the carrier 710). In some embodiments, all dies 730 are placed face down, and thinned by backside grinding after bonding. This enables thin dies 730. In these embodiments, the TSVs 731 may be fabricated before or after the dies 730 are attached.

Referring now to FIG. 7B, a cross-sectional illustration of the device 720 after a dielectric layer 733 is provided around the first dies 730 is shown, in accordance with an embodiment. The dielectric layer 733 may be any suitable dielectric material, such as a buildup film, a molding material, an oxide, a nitride, and/or the like. In an embodiment, the dielectric layer 733 is planarized with a top surface of the first dies 730.

In an embodiment, vias 732 may be formed through a thickness of the dielectric layer 733.

Referring now to FIG. 7C, a cross-sectional illustration of the device 720 after an HBI layer 738 is formed over the first dies 730 and the dielectric layer 733. The HBI layer 738 may comprise a dielectric material (e.g., an oxide or a nitride) that comprises pads 739. The pads 739 may have a top surface that is substantially coplanar with a top surface of the HBI layer 738. Vias may couple the pads 739 to electrical structures in the underlying dielectric layer 733 or within the first dies 730. The HBI layer 738 may be formed with any suitable patterning processes, deposition processes, and/or the like.

Referring now to FIG. 7D, a cross-sectional illustration of the device 720 after second dies 740 are coupled to the first dies 730 is shown, in accordance with an embodiment. The second dies 740 may also comprise an HBI layer 744 with pads 746. The pads 746 and the pads 739 may be fusion bonded, while the HBI layer 744 and the HBI layer 738 are also bonded through diffusion. As shown in FIG. 7D, a second die 740 may be electrically coupled to two or more first dies 730 in some embodiments.

Referring again to FIG. 7D, a cross-sectional illustration of the device 720 after a second dielectric layer 745 is provided around the second dies 740 is shown, in accordance with an embodiment. In an embodiment, the second dielectric layer 745 may be the same material as the dielectric layer 733.

Referring now to FIG. 7E, a cross-sectional illustration of the device after a receiving wafer 748 is coupled to the second dies 740 is shown, in accordance with an embodiment. In an embodiment, the receiving wafer 748 may be a silicon wafer or the like. In an embodiment, the receiving wafer 748 may be bonded to the device 720 with a wafer bonding process.

Referring now to FIG. 7F, a cross-sectional illustration of the device 720 after the carrier 710 is removed is shown, in accordance with an embodiment. The carrier 710 may be removed with an IR radiation exposure process similar to any such processes described in greater detail herein. For example, an IR laser may expose the debond film through the carrier substrate. The carrier substrate can then be removed. In some embodiments, the bonding layer 707 may remain on the device 720.

Referring now to FIG. 7G, a cross-sectional illustration of an electronic system 700 that includes the device 720 is shown, in accordance with an embodiment. As shown, the device 720 is attached to a board 760, such as a printed circuit board (PCB), a motherboard, or the like. The device 720 may include any suitable second level interconnect (SLI) architecture for coupling with the board 760. For example, solder bumps 761 on pads 762 may be used. Pins, sockets, and/or the like may also be used for the SLI architecture.

In FIGS. 7A-7G, a hybrid bonding process is provided in order to provide die-to-die coupling in different layers. However, other embodiments may also include a fusion bonding process when a single layer with a die (or dies) is needed. For example, the layer of dies may be embedded in a bonding oxide, and a second carrier is attached to the top of the layer with the fusion bonding process (i.e., a dielectric-to-dielectric bonding process). In an embodiment, the original carrier is released with an IR laser ablation process similar to those described in greater detail herein. The released dies can then be thinned while secured by the second carrier or processed in any other desired manner.

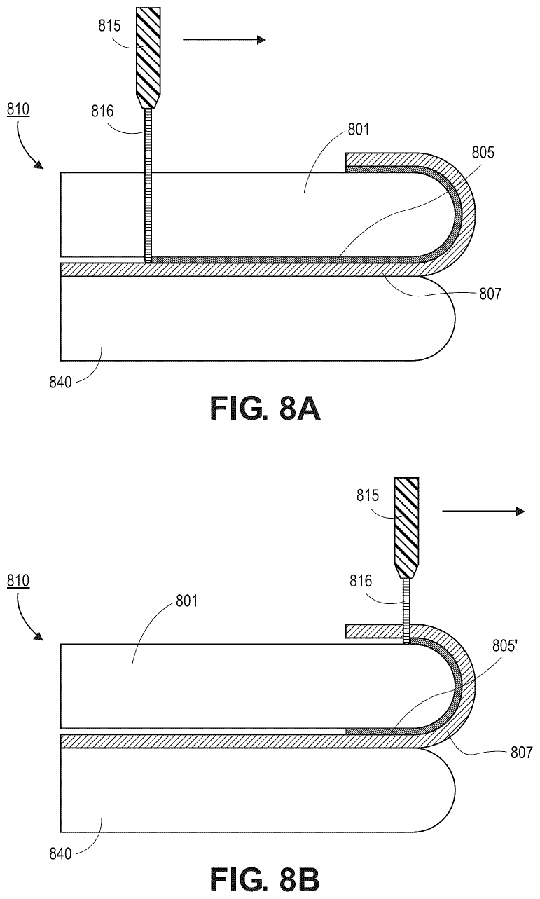

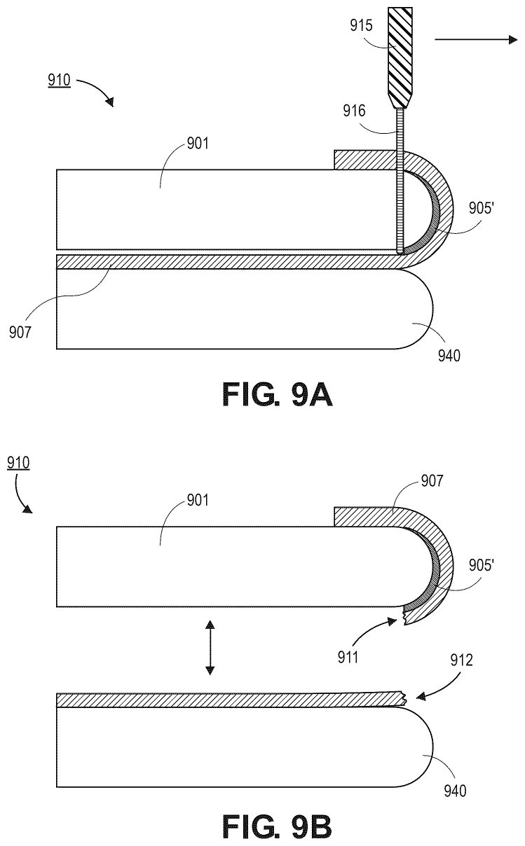

In embodiments disclosed herein, the debond and other films were described without reference to the edge of the wafer. However, in some embodiments the debond and other films wrap around the edge surface or bevel of the carrier substrate. This can generate issues with the release process, as will be described with some simplified examples in FIGS. 8A-9B.

In FIG. 8A, a carrier 810 comprises a substrate 801 with a debond film 805 and a bonding layer 807. Due to deposition processes, the debond film 805 may wrap around an edge of the substrate 801 and also be provided on a back surface of the substrate 801. A structure 840 is attached to the bonding layer 807. In order to release the structure 840, a laser 815 exposes the debond film 805 with IR radiation 816. This works well, until the laser 815 reaches the edge of the substrate 801.

As shown in FIG. 8B, the IR radiation 816 is blocked by the portion of the debond film 805 on the backside of the substrate 801. This prevents complete removal of the debond film 805′ on the front side of the substrate 801. As such, it may be difficult to remove the structure 840. It should be appreciated that for the embodiments described in Figure sets 1-7, there are other films deposited besides the debond and bond films 805 and 807 respectively, including sometimes much thicker films, such as the oxide fill layers in FIGS. 6A-6G and 7A-7G, which in some embodiments also wrap around the bevel.

Referring now to FIGS. 9A and 9B, an additional issue arises. As shown, the carrier 910 has a substrate 901 with a debond film 905 and a bonding layer 907. The structure 940 is attached by the bonding layer 907. However, as the debond film 905′ is removed by the laser 915 and IR radiation 916, the bonding layer 907 persists. Since the bonding layer 907 wraps around the substrate 901, it is difficult to remove the structure 940. As shown in FIG. 9B, the bonding layer 907 needs to be broken. This may result in irregular surfaces 911 and 912 being formed, which may be undesirable. It should be appreciated that for the embodiments described in Figure sets 1-7, there are other films deposited besides the debond and bond films 905 and 907 respectively, including sometimes much thicker films, such as the oxide fill layers in FIGS. 6A-6G and 7A-7G, which in some embodiments also wrap around the bevel, and further exacerbates the problems. Also, the example problems illustrated in FIGS. 8A-8B and 9A-9B are not the only potential problems from having these films wrap around the edge. Other possible problems include interfering with the bonding process, and crack formation and flaking during the debond process.

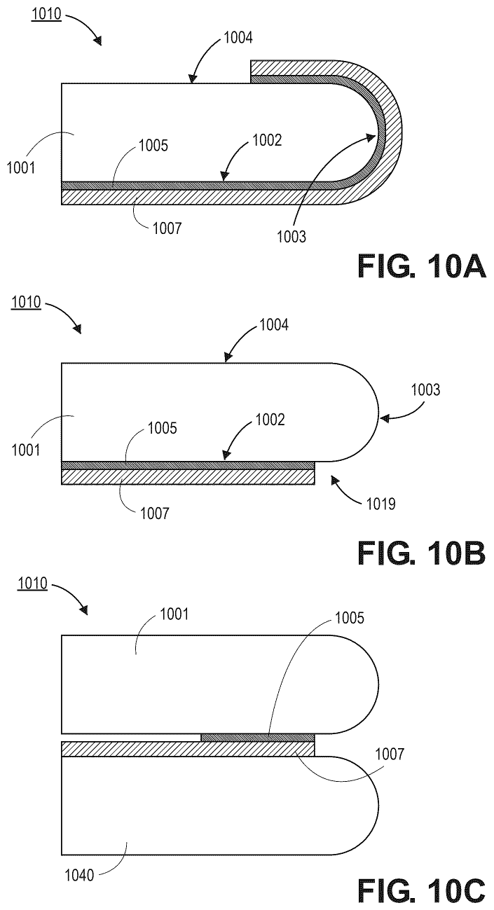

Accordingly, embodiments disclosed herein may include a process for treating an edge of the carrier to remove the debond film and boding layer that wraps around an edge of the carrier. An example of such a process is shown in FIGS. 10A-10C.

Referring now to FIG. 10A, a cross-sectional illustration of a portion of a carrier 1010 is shown, in accordance with an embodiment. The carrier 1010 may comprise a substrate 1001 with a front surface 1002, an edge surface 1003, and a backside surface 1004. As shown, the debond film 1005 and the bonding layer 1007 may cover the front surface 1002, wrap around the edge surface 1003, and cover at least a portion of the backside surface 1004.

Referring now to FIG. 10B, a cross-sectional illustration of the carrier 1010 after an etching process is shown, in accordance with an embodiment. As shown, the etching process removes the debond film 1005 and the bonding layer 1007 from the edge surface 1003 and the backside surface 1004. Additionally, an edge region 1019 along the perimeter of the front surface 1002 may be cleared. The etching process may include a wet etching process, a dry etching process, a laser ablation process, or any other suitable subtractive process. It should be appreciated that for the embodiments described in Figure sets 1-7, there are other films deposited besides the debond and bond films 1005 and 1007 respectively, including sometimes much thicker films, such as the oxide fill layers in FIGS. 6A-6G and 7A-7G, which in some embodiments also wrap around the bevel. For those embodiments, the film 1007 represents a plurality of films deposited on the debond film 1005.

Referring now to FIG. 10C, a cross-sectional illustration of the carrier 1010 after a structure 1040 is attached and an IR laser ablation process has partially removed the debond film 1005. As shown, the debond film 1005 is unobstructed, and the bonding layer 1007 is not connected to anything but the structure 1040 after the debond film 1005 is completely removed. As such, a clean and simple release process may be enabled when an edge etching process is used on the carrier 1010.

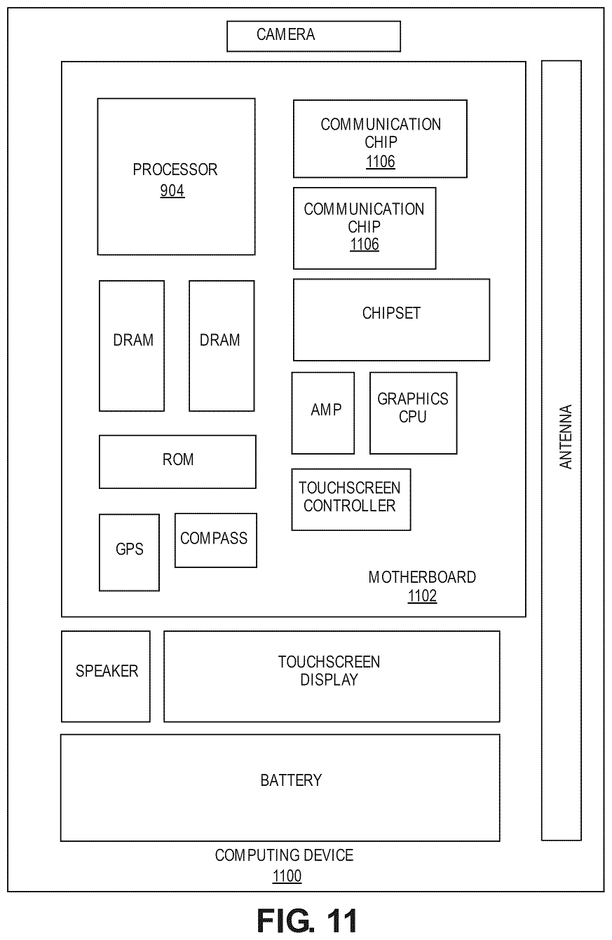

FIG. 11 illustrates a computing device 1100 in accordance with one implementation of the disclosure. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1104. In some implementations of the disclosure, the integrated circuit die of the processor may be part of an electronic package that is fabricated through the use of a carrier wafer with a debond film that is deactivated with an IR laser, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation of the disclosure, the integrated circuit die of the communication chip may be part of an electronic package that is fabricated through the use of a carrier wafer with a debond film that is deactivated with an IR laser, in accordance with embodiments described herein.

In an embodiment, the computing device 1100 may be part of any apparatus. For example, the computing device may be part of a personal computer, a server, a mobile device, a tablet, an automobile, or the like. That is, the computing device 1100 is not limited to being used for any particular type of system, and the computing device 1100 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a method, comprising: positioning a first structure over a second structure, wherein the first structure comprises a first electrical pad over a carrier substrate, wherein the first structure is mechanically coupled to the carrier substrate by a debond film, and wherein the second structure comprises a second electrical pad; bonding the first electrical pad to the second electrical pad with a hybrid bonding process; ablating at least a portion of the debond film with a laser with a wavelength in an infrared range; and removing the carrier substrate.

Example 2: the method of Example 1, wherein the first electrical pad is on a first die that is mounted to the carrier substrate, and wherein the second electrical pad is on a second die.

Example 3: the method of Example 2, wherein the first structure further comprises a third die, and wherein the second die is hybrid bonded to the first die and the third die.

Example 4: the method of Examples 1-3, wherein the first and second structures comprise a wafer with a device layer, and wherein the device layer comprises one or more of a transistor, a capacitor, an inductor, or a resistor.

Example 5: the method of Examples 1-4, wherein the first structure and the second structure have wafer form factors.

Example 6: the method of Examples 1-5, wherein the debond film comprises: a metallic layer; and a dielectric layer.

Example 7: the method of Example 6, wherein the metallic layer comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

Example 8: the method of Example 6 or Example 7, wherein the dielectric layer comprises one or more of silicon, oxygen, nitrogen, carbon, aluminum, titanium, hafnium, zirconium, or tantalum.

Example 9: the method of Examples 1-8, wherein the first electrical pad is offset from the second electrical pad.

Example 10: the method of Examples 1-9, further comprising: etching an edge of the carrier substrate to remove all films from an edge of the carrier substrate.

Example 11: a carrier substrate, comprising: a substrate, wherein the substrate comprises a material that is at least partially transparent to infrared radiation; a debond film over the substrate, wherein an edge of the debond film is set back from an edge of the substrate, and wherein the debond film comprises: a first metallic layer on the substrate; and a dielectric layer over the first metallic layer; and a second metallic layer over the dielectric layer.

Example 12: the carrier substrate of Example 11, wherein the substrate comprises silicon, germanium, sapphire, silicon and carbon, or glass.

Example 13: the carrier substrate of Example 11 or Example 12, wherein the substrate is a wafer with at least a 200 mm diameter.

Example 14: the carrier substrate of Examples 11-13, wherein the first metallic layer comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

Example 15: the carrier substrate of Examples 11-14, wherein the dielectric layer comprises one or more of silicon, oxygen, nitrogen, carbon, aluminum, titanium, hafnium, zirconium, or tantalum.

Example 16: the carrier substrate of Examples 11-15, wherein the debond

layer has a thickness up to 200 nm.

Example 17: the carrier substrate of Examples 11-16, wherein the substrate has a (100) crystal orientation, a (110) crystal orientation, or a (111) crystal orientation.

Example 18: a method of forming an electronic device, comprising: attaching a first wafer to a carrier substrate, wherein the carrier substrate comprises a debond film between the carrier substrate and the first wafer; thinning the first wafer; forming vias through the first wafer; attaching a second wafer to first wafer with a hybrid bonding process; and removing the carrier substrate with an infrared laser treatment of the debond film.

Example 19: the method of Example 18, wherein the first wafer and the second wafer are singulated after removing the carrier substrate.

Example 20: the method of Example 18 or Example 19, wherein the electronic device is part of a personal computer, a server, a mobile device, a tablet, or an automobile.

What is claimed is:

1. A method, comprising:
positioning a first structure over a second structure, wherein the first structure comprises a first electrical pad over a carrier substrate, wherein the first structure is mechanically coupled to the carrier substrate by a debond film, and wherein the second structure comprises a second electrical pad;
bonding the first electrical pad to the second electrical pad with a hybrid bonding process or a fusion bonding process;
ablating at least a portion of the debond film with a laser with a wavelength in an infrared range; and
removing the carrier substrate.

2. The method of claim 1, wherein the first electrical pad is on a first die that is mounted to the carrier substrate, and wherein the second electrical pad is on a second die.

3. The method of claim 2, wherein the first structure further comprises a third die, and wherein the second die is hybrid bonded to the first die and the third die.

4. The method of claim 1, wherein the first and second structures comprise a wafer with a device layer, and wherein the device layer comprises one or more of a transistor, a capacitor, an inductor, or a resistor.

5. The method of claim 1, wherein the first structure and the second structure have wafer form factors.

6. The method of claim 1, wherein the debond film comprises:
a metallic layer; and
a dielectric layer.

7. The method of claim 6, wherein the metallic layer comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

8. The method of claim 6, wherein the dielectric layer comprises one or more of silicon, oxygen, nitrogen, carbon, aluminum, titanium, hafnium, zirconium, or tantalum.

9. The method of claim 1, wherein the first electrical pad is offset from the second electrical pad.

10. The method of claim 1, further comprising:
etching an edge of the carrier substrate to remove all films from an edge of the carrier substrate.

11. A carrier substrate, comprising:
a substrate, wherein the substrate comprises a material that is at least partially transparent to infrared radiation;
a debond film over the substrate, wherein an edge of the debond film is set back from an edge of the substrate, and wherein the debond film comprises:
a first metallic layer on the substrate; and
a dielectric layer over the first metallic layer; and
a second metallic layer over the dielectric layer.

12. The carrier substrate of claim 11, wherein the substrate comprises silicon, germanium, sapphire, silicon and carbon, or glass.

13. The carrier substrate of claim 11, wherein the substrate is a wafer with at least a 200 mm diameter.

14. The carrier substrate of claim 11, wherein the first metallic layer comprises one or more of aluminum (Al), tungsten (W), copper (Cu), titanium (Ti), tantalum (Ta), niobium (Nb), chromium (Cr), hafnium (Hf), molybdenum (Mo), manganese (Mn), zirconium (Zr), palladium (Pd), platinum (Pt), gold (Au), silver (Ag), or ruthenium (Ru).

15. The carrier substrate of claim 11, wherein the dielectric layer comprises one or more of silicon, oxygen, nitrogen, carbon, aluminum, titanium, hafnium, zirconium, or tantalum.

16. The carrier substrate of claim 11, wherein the debond layer has a thickness up to 200 nm.

17. The carrier substrate of claim 11, wherein the substrate has a (100) crystal orientation, a (110) crystal orientation, or a (111) crystal orientation.

18. A method of forming an electronic device, comprising:
attaching a first wafer to a carrier substrate, wherein the carrier substrate comprises a debond film between the carrier substrate and the first wafer;
thinning the first wafer;
forming vias through the first wafer;
attaching a second wafer to first wafer with a hybrid bonding process; and
removing the carrier substrate with an infrared laser treatment of the debond film.

19. The method of claim 18, wherein the first wafer and the second wafer are singulated after removing the carrier substrate.

20. The method of claim 18, wherein the electronic device is part of a personal computer, a server, a mobile device, a tablet, or an automobile.
